(19) United States
(12) Patent Application Publication
(10) Pub. No.: US 2009/0302870 A1
(43) Pub. Date: Dec. 10, 2009

(54) Soil moisture sensor with data transmitter

(76) Inventors: Neil D. Paterson, South Australia (AU); Richard J. Cave, South Australia (AU); Neil M. Wilson, South Australia (AU)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 12/310,946

(22) PCT Filed: Sep. 12, 2007
(86) PCT No.: PCT/AU2007/001348

§ 371 Date: Aug. 10, 2009

(30) Foreign Application Priority Data
Sep. 12, 2006 (AU) 2006904995

(51) Int. Cl. G01R 27/26

(52) U.S. Cl. 324/670

(57) ABSTRACT

A sensor and method for sensing moisture content of a medium such as soil is disclosed. In an embodiment, the sensor includes a sensing circuit, a processing module, a register, and a communications interface for communicatively coupling the sensor to an external communications device. In use, the sensing circuit generates a sensed signal having a signal parameter value attributable to the moisture content of the medium. The processing module processes the signal parameter value to provide, at an output, a scaled data value. The register stores a sensor identifier for the sensor and the communications interface is capable of communicating the scaled data value and the sensor identifier to the external device. An irrigation control system is also disclosed.

This international patent application claims priority from Australian provisional patent application no. 2006904995 filed on 12 Sep. 2006, the contents of which are to be taken as incorporated herein by this reference.

### FIELD OF THE INVENTION

The present invention broadly relates to sensors for sensing an environmental parameter, such as moisture content, temperature, or salinity of a medium. In a typical application the sensor may be used for sensing the moisture content of a medium, such as a soil medium.

### BACKGROUND TO THE INVENTION

Measurement of soil parameters, such as soil moisture content, enables an agriculturist to visualise a crop's response to irrigation and other practices, and to better understand crop and soil water relationships. For example, information obtained from such measurements may be used by an agriculturist to assist with day to day soil management decisions to thereby improve productivity and sustainability as well as to provide improved management of increasingly limited water resources.

Thus, a critical step in the management of water usage for agricultural activities, particularly in context of irrigation management, is the monitoring of soil moisture content. In particular, provided that the information obtained from such monitoring is accurate, such information may be useful in determining when to irrigate a crop and even how much irrigation to apply.

In recent years, different types of soil moisture sensors have been developed. Of those sensors, sensors that rely on measurements attributable to a soil medium's dielectric constant have emerged as providing the most promise in that they tend to provide faster, more accurate information as compared to traditional sensors such as resistance, tensiometric and heat dissipation based soil moisture sensors.

One type of dielectric constant based sensor is a capacitance based sensor which employs radio frequency signals to determine a soil medium's dielectric constant to thereby infer soil moisture content. Sensors of this type typically rely on measuring a frequency change in a radio frequency signal of an oscillator circuit having a capacitive sensing element (for example, an electrode) which projects an electric field into the soil medium being measured.

The capacitive sensing element typically includes cylindrical plates located within an access tube, or other suitable housing, which is insertable into the soil medium. Usually, the plates are separated from the soil medium by the housing of the access tube.

Of course, in order for the information provided by a soil moisture sensor to be useful, the information must be accurate. Unfortunately, in traditional sensors, external factors can contribute to a reduction in the accuracy of the sensed information or cause measurement variations. Such factors may include, for example, soil temperature and the type of the soil medium. In other words, the sensed information is not solely dependent on the sensed soil moisture, but also on additional parameters unrelated to soil moisture content.

In practice, the reduction in the accuracy of a sensed soil moisture value may be addressed by configuring a sensor to compensate for the effect of those factors. For example, a soil moisture sensor may be calibrated for a specific type of soil medium (for example, clay or sand). However, once a sensor is configured and then positioned in the soil medium, it may not be possible to identify the configuration of the sensor without performing a visual inspection.

It is an object of the present invention to provide a soil moisture sensor which ameliorates at least one of the aforementioned deficiencies of existing soil moisture sensors.

The discussion of the background to the invention herein is included to explain the context of the invention. This is not to be taken as an admission that any of the material referred to was published, known or part of the common general knowledge as at the priority date of any of the claims.

### SUMMARY OF THE INVENTION

In broad terms, the present invention provides a sensor for sensing an environmental parameter of a medium, such as a soil. The sensor generates a sensed signal having a signal parameter value attributable to the environmental parameter, and processes the signal parameter value to communicate, to an external communications device, a data value indicative of the sensed environmental parameter together with a sensor identifier. The sensor identifier may serve a variety of purposes. For example, it may be used to uniquely identifier the configuration of the sensor, such as by way of serial number. Alternatively, the identifier may identify a characteristic of the sensor such as the software version of an installed software program, or a hardware version. Alternatively, it may be used for ‘plug and play’ type communications with the external communications device.

The present invention also provides a sensor for sensing moisture content of a medium such as soil, the sensor including: a sensing circuit for generating a sensed signal having a signal parameter value attributable to the moisture content of the medium; a processing module for processing the signal parameter value to provide, at an output, a scaled data value; a register for storing a sensor identifier for the sensor; and a communications interface for communicatively coupling the sensor to an external communications device to communicate the scaled data value and the sensor identifier thereto.

The present invention also provides an irrigation control system for controllably interrupting a programmed irrigation cycle, the irrigation control system including:

a sensor including a sensing circuit for generating a sensed signal having a signal parameter value attributable to moisture content of a medium such as soil and a processing module for processing the signal parameter value to provide, at an output, a scaled data value; a register for storing a sensor identifier for the sensor; and a communications interface for communicatively coupling the sensor to an external communications device to communicate the scaled data value and the sensor identifier thereto; and

an external communications device including a user-settable input for entering a high-set point level value; and a comparator for comparing the scaled data value with the high-set point value to provide, responsive to the comparison, a control signal for actuating a switching means to interrupt the programmed irrigation cycle.

The present invention also provides a sensor for sensing moisture content of a medium such as soil, the sensor including:

a sensing circuit for generating a sensed signal having a signal parameter value attributable to the moisture content of the medium, the sensing circuit including an oscillator configured such that when the sensor is inserted into the medium the oscillator generates the sensed signal, the sensed signal having a frequency signal parameter value (f_{osc}) that varies according to a dielectric constant of the medium;

a processing module for processing the signal parameter value to provide, at an output, a scaled data value (S_{F}), the processing including deriving a count value (F_{S}) of the sensed signal (f_{osc}) detected during a gate time, and processing the count value (F_{S}), and frequency values indicative of in air (F_{α}) and in water (F_{W}) frequency values respectively to calculate the scaled data value S_{F} wherein:

$${S}_{F} = \frac{( {F}_{a} - {F}_{s} )}{( {F}_{a} - {F}_{W} )} ;$$

a register for storing a sensor identifier for the sensor; and

a communications interface for communicatively coupling the sensor to an external communications device to communicate the scaled data value and the sensor identifier thereto.

The present invention also provides a computer readable medium containing a computer software program for programming a sensor for sensing moisture content of a soil medium, the software program being executable by a processor module to cause the sensor to:

generate a sensed signal having a signal parameter value attributable to the moisture content of the medium;

process the signal parameter value to provide, at an output, a scaled data value;

access a register to retrieve a sensor identifier for the sensor; and

activate a communications interface communicatively coupling the sensor to an external communications device to communicate the scaled data value and the sensor identifier thereto.

The present invention also provides a method of obtaining a measurement value from a sensor for sensing moisture content of a medium such as soil, the method including:

inserting the sensor into the medium having a moisture content;

the sensor generating a sensed signal having a signal parameter value attributable to the moisture content of the medium;

controlling a processing module associated with the sensor to:
process the signal parameter value to provide, at an output of the sensor, a scaled data value;
access a register to retrieve a sensor identifier for the sensor; and
activate a communications interface communicatively coupling the sensor to an external communications device to communicate the scaled data value and the sensor identifier thereto.

### GENERAL DESCRIPTION OF THE INVENTION

Before turning to a description of various aspects of embodiments of the present invention, it is to be appreciated that although the description that follows relates to the application of a sensor for sensing moisture content of a soil medium, it is envisaged that different embodiments of the sensor may be applicable to sensing moisture content in other mediums. In addition, a sensor in accordance with the present invention is not to be construed as being limited to sensing moisture content. For example, in other applications the sensor may be configured to sense other environmental parameters such as humidity, salinity and temperature.

Turning now to a description of various aspects of embodiments of the present invention, in one embodiment the sensing circuit includes an oscillator that itself includes a paired electrode arrangement providing a capacitive element having a value of capacitive reactance. In use, the capacitive reactance has a value that is attributable to the dielectric constant of the medium and thus attributable to moisture content.

The oscillator may include a balanced very high frequency (VHF) voltage controlled oscillator tuned via a differential capacitance circuit that includes the capacitive element. In an embodiment, the oscillator has a resonant frequency that varies over a range of substantially 90.00 MHz to 170 Mhz.

The paired electrode arrangement may include a pair of cylindrical conductive elements, or alternatively it may include a pair of planar electrodes. In this respect, in an embodiment that includes planar electrodes, the planar electrodes may be single end-driven or centrally driven.

The signal parameter value attributable to moisture content may be a signal parameter value that is sensed from the sensed signal directly. In other words, the signal parameter value may include a sensed voltage, current, period, frequency or phase. However, in an embodiment, the sensed signal parameter value is a frequency value of the sensed signal. In such an embodiment, processing of the frequency value by the processing module may include counting, throughout a predetermined interval of time (or gate time), the frequency of a signal that has been derived from the sensed signal and subsequently processing that signal to derive a scaled data value in a form of a scaled frequency data value.

In another embodiment, the signal parameter value attributable to moisture content is a signal parameter value sensed by a comparison with a reference signal having a fixed time base or frequency. For example, in another embodiment, the signal parameter value is a phase difference between the sensed signal and a fixed frequency reference signal.

The processing module may include a programmed controller, such as a micro-controller, including on-board memory containing program instructions in a form of application code. One suitable processing module is, for example, a ATMEGA168 controller including 16 Kbyte on-board memory. It is expected the processing module will provide significant flexibility in operation and capabilities of the sensor that may provide further benefits over existing soil moisture sensors. For example, the processing module may be configured to revert to an ‘idle mode’ between consecutive sensing cycles, or after a predefined set of sensing cycles. In this respect, for the purposes of this description an ‘idle mode’ includes a mode in which selected components of the sensor are isolated from electrical power. In ‘idle mode’, components that provide voltage regulation functions, including the communication interface, and the controller may remain powered. However, in an embodiment, the controller also switches to an idle mode to thereby turn off all internal activity besides an internal low power timer and a communication interrupt to detect activation of an active mode. A controller that provides an ‘idle mode’ may have a lower overall power demand which may be advantageous, for example, for embodiments that are powered by limited supply sources such as batteries, or solar cells. In this respect, in one embodiment, when the active mode is enabled and a sensing cycle is invoked on a sensor assembly that includes multiple sensors, only one sensor may be powered up at a time.

The register storing the sensor identifier may include a hard-wired register configured using, for example, jumper-links, or a switch (such as a dual-in-line switch or a rotary switch). However, in an embodiment the register includes an addressable entry in on-board memory. Indeed, in one embodiment the register stores a sensor identifier, in the form of a device serial number (DSN), as a four-byte (that is, thirty-two bits) unsigned integer. It will be appreciated that it is not essential that a four-byte unsigned integer be used. However, a four-byte integer will provide 4,294,297,296 possible unique sensor identifiers, which is expected to be adequate for each sensor to have a unique sensor identifier. As will be appreciated, a smaller sensor identifier may be used with a resultant reduction in the available number of unique sensor identifiers (for example, a 2 bytes integer would provide 65,535 possible sensor identifiers).

Communication of the scaled data value and the sensor identifier to the external communications device may occur periodically, perhaps under the control of, and responsive to, a timer on-board the sensor. As will be appreciated, such a timer may be implemented in hardware or in software. For example, the timer may be implemented as a software module in application code on-board the sensor. However, in one embodiment, the communication of the scaled data value and the sensor identifier to an external communications device occurs in response to a request from the external communications device. In other words, the sensor outputs the scaled data value and the sensor identifier in response to a request from the external communication device. Thus, in one embodiment, the communications interface is a bi-directional communications interface.

The scaled data value may be obtained after conducting a single sensing cycle or, alternatively, it may be obtained after conducting plural sensing cycles. In this respect, ‘sensing cycle’ denotes a sensing process in which the sensed signal, and thus the signal parameter value, is sensed once. In an embodiment that obtains the scaled data value after processing plural sensing cycles, the processing may include statistical processing, such as ‘moving average’ processing for a defined set of sensing cycles, and thus scaled data values.

The inclusion of the bi-directional communications interface may provide significant advantages in that it may permit configuration of the sensor to be modified without dismantling the sensor. By way of example, an embodiment of the sensor that includes a bi-directional communications interface may be equipped with suitable computer software that permits the application code to be upgraded via the bi-directional communications interface. In terms of another example, a bi-directional communications interface may allow processing of the signal parameter value attributable to the soil moisture to be configurable via the bi-directional communications interface. Indeed, in one embodiment, the sensor includes an on-board memory storing processing parameter values that are settable via the bi-directional communications interface. Such parameter values may include parameter values that are related to, or set depending on, the soil type of the soil medium, temperature compensation factors, and sensing cycle timing.

An embodiment of the sensor may include an integral temperature sensor for sensing the temperature within a sensed zone of the soil medium. In other words, the sensor may include an integral temperature sensor that senses temperature of the soil medium at substantially the same location that soil moisture is being sensed. In an embodiment that includes a temperature sensor, processing of the sensed signal may include applying a temperature compensation factor based on sensed temperature so that a scaled data value is temperature compensated. A sensor that includes an integral temperature sensor, and that also provides suitable temperature compensation processing, may provide scaled data values that are independent of temperature. As a result, such a sensor may provide scaled data values that are compensated for diurnal fluctuations directly within the sensor.

Although an embodiment of the sensor provides temperature compensated scaled data values, it is to be appreciated that another embodiment may provide, at an output and in addition to the scaled data values, temperature data indicative of the sensed temperature. In such an embodiment, temperature compensation of the scaled data values may take place during a processing step conducted remotely from the sensor, possibly by a second processing module associated with the external communications device.

Embodiments of the present invention may find application in numerous areas of application. For example, a sensor in accordance with an embodiment of the present invention may be used in irrigation applications such as agricultural irrigation, viticultural irrigation, horticultural irrigation, domestic and commercial garden irrigation, urban open space irrigation, turf-grass irrigation, and sports playing field (such as golf course irrigation). Of course, it will be appreciated that the present invention is not limited to irrigation applications. Indeed, the present invention could also find application in site remediation monitoring, mining site dewatering control, sewerage and drainage control, construction site environmental monitoring, industrial, commercial and process plant/process/air handling monitoring, domestic, commercial and industrial building footings, geotechnical monitoring and control, environmental monitoring, and underground tunnel geotechnical monitoring.

### BRIEF DESCRIPTION OF THE DRAWINGS

The invention will now be described in further detail by reference to the attached drawings illustrating example forms of the invention. It is to be understood that the particularity of the drawings does not supersede the generality of the invention.

In the drawings:

FIG. 1A is a simplified block diagram of a sensor in accordance with an embodiment of the present invention;

FIG. 1B is a simplified block diagram of a sensor in accordance with a second embodiment of the present invention;

FIG. 2 is a detailed block diagram of the embodiment of the sensor shown in FIG. 1A;

FIG. 3 is a schematic diagram of a circuit for a sensor in accordance with the embodiment illustrated in FIG. 2;

FIG. 4A is a front view of a sensor in accordance with an embodiment of the present invention;

FIG. 4B is an end view of the sensor depicted in FIG. 4A;

FIG. 5 is an exploded view of a sensor in accordance with another embodiment of the present invention;

FIG. 6 is a block diagram of an irrigation system incorporating a sensor and a level controller in accordance with an embodiment of the present invention;

FIG. 7 is another block diagram of the irrigation system depicted in FIG. 6; and

FIG. 8 is a block diagram of an irrigation system incorporating a level controller and plural sensors in accordance with an embodiment of the present invention; and

FIG. 9 is a flow diagram of a method of obtaining a measurement value from a sensor according to an embodiment of the invention.

### DETAILED DESCRIPTION OF A PREFERRED EMBODIMENT

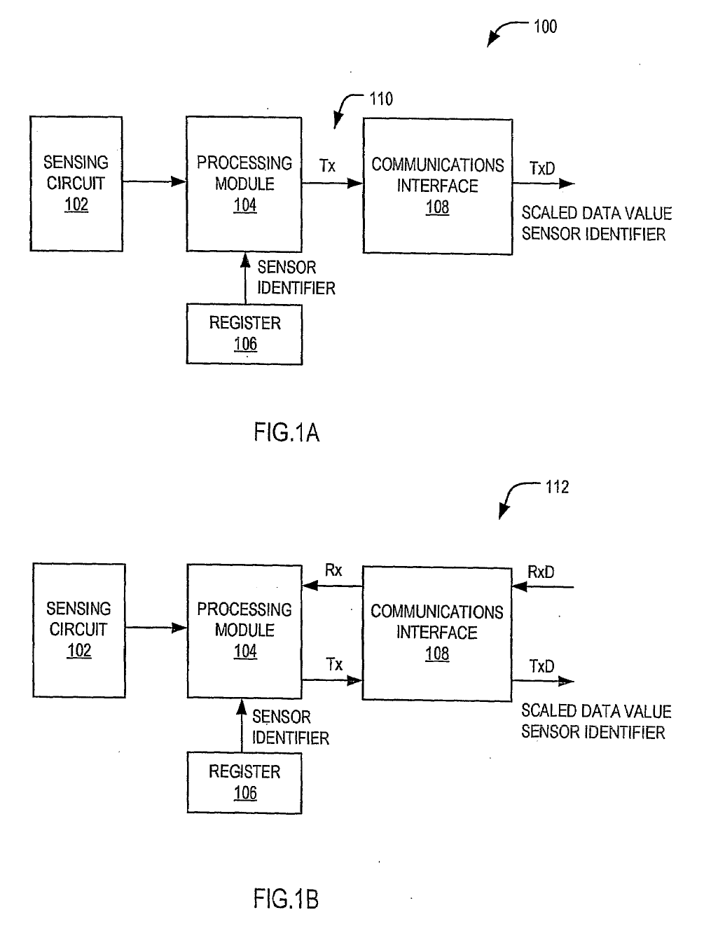

FIG. 1A depicts a simplified block diagram of a soil moisture sensor 100 in accordance with an embodiment of the present invention. As is shown, the sensor 100 includes a sensing circuit 102, a processing module 104, a register 106, and a communications interface 108.

The sensing circuit 102 generates a sensed signal having a signal parameter value attributable to moisture content of a soil medium. The processing module 104 processes the signal parameter value to provide, at an output 110, a scaled data value.

The register 106 stores a sensor identifier for the sensor 100 and may include, for example, an addressable memory entry containing data representative of the sensor identifier.

The communications interface 108, has an output data port (T×D), and is configured for communicatively coupling the sensor 100 to an external communications device (not shown) so as to communicate the scaled data value and the sensor identifier thereto. Communicating the scaled data value and the sensor identifier to the communications device may allow that device, or another suitable device (such as a computer) coupled to the communications device, or having access to the communicated information (such as via a database) to obtain additional information about the configuration of the sensor 100 by, for example, indexing the sensor identifier into a database containing configuration information associated with the sensor identifier. In other words, a user may be then be able to conduct further processing of the scaled data value based on the configuration information, if required. Such further processing may include, for example, applying a temperature compensating factor to the scaled data value based on temperature measurements obtained from a temperature sensor located near the identified sensor, such as may be identified by a database associating soil moisture sensor location with temperature sensor location, or similar.

FIG. 1B depicts a simplified block diagram of a soil moisture sensor 112 in accordance with a second embodiment of the present invention. As is shown, the sensor 112 also includes a sensing circuit 102, a processing module 104, a register 106, and a communications interface 108. However, in the second embodiment, the communications interface 108 is a bi-directional communications interface including an output data port (T×D) and an input data port (R×D).

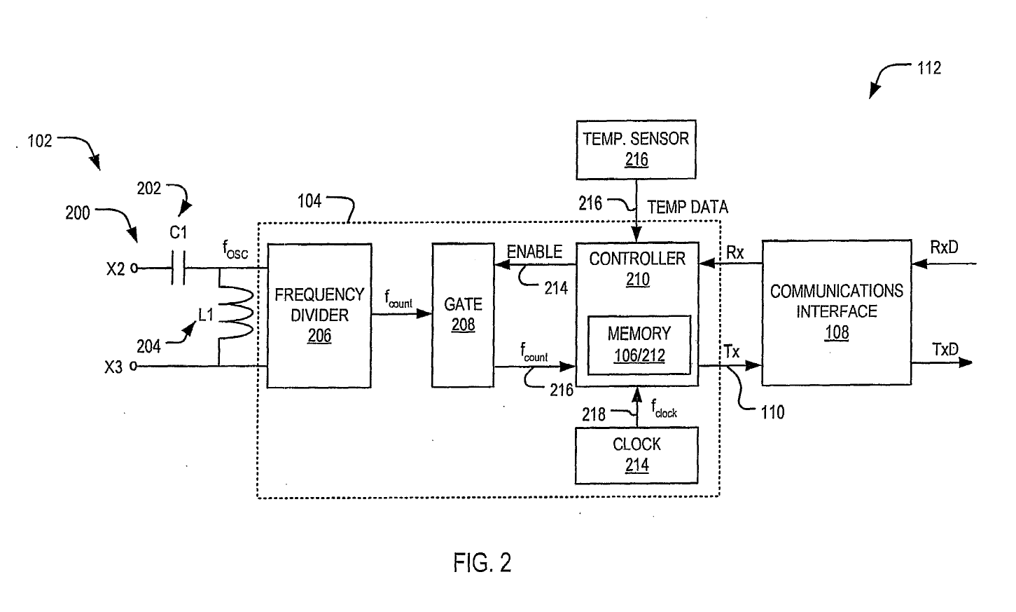

FIG. 2 depicts a more detailed block diagram of a sensor 112 in accordance with the second embodiment. Since the sensing circuit 102, the processing module 104, and the register 106 are common to the sensor 100 as well as the sensor 112, the description that follows is applicable, at least in relation to the common components, to each sensor 100, 112. Thus, although the following description will refer to the sensor 112, it is to be appreciated that the description of the common elements is also applicable to the sensor 100 (ref. FIG. 1).

Thus, with reference now to FIG. 2, and turning firstly to the sensing circuit 102, the illustrated sensing circuit 102 includes an oscillator 200 that generates a sensed signal having a frequency signal parameter value (f_{osc}) that varies according to the dielectric constant of the soil medium, and thus the soil moisture content.

For ease of understanding, the oscillator 200 is depicted here in a simplified form. As depicted, the oscillator 200 includes sensing elements X2, X3 coupled in parallel with a series LC arrangement represented as bulk capacitance (C1) 202 and bulk inductance (L1) 204.

For reasons that will be explained below, the depicted arrangement of the sensing elements X2, X3, the bulk capacitance 202 and bulk inductance 204 forms a resonant circuit having a resonant frequency f_{osc}.

The sensing elements X2, X3 include either a pair of co-planar planar conductive electrodes or a pair of co-axially arranged cylindrical conductive electrodes. Advantageously, a sensor 112 that includes planar electrodes is able to sense soil moisture on both sides of the planar electrode. However, irrespective of the mechanical configuration of the sensing elements X1, X2, the electrode pair X2, X3 will be arranged to project an electric field into the soil medium when the sensor 112 is located within that medium. As will be appreciated, the electric field extends between the electrodes X2, X3.

The processing module 104, shown in FIG. 2 includes a frequency divider 206, a gate 208, a controller 210, on-board memory 106/212, and a clock 214. As explained previously, the function of the processing module 104 is to processes a signal parameter value (in this case f_{osc}) of the sensed signal to provide, at the output 110, a scaled data value indicative of the soil moisture content. In the embodiment illustrated in FIG. 2 the processing of the frequency f_{osc} of the sensed signal includes dividing the sensed frequency using the frequency divider 206 to provide a low frequency signal fount for further processing by the controller 210. In the present case, the further processing entails, counting the number of cycles of the f_{count} that occur in “The processing module 104, shown in FIG. 2 includes a frequency divider 206, a gate 208, a controller 210, on-board memory 106/212, and a clock 214.

As explained previously, the function of the processing module 104 is to processes a parameter (in this case f_{osc}) of the sensed signal to provide, at the output 110, a scaled data value indicative of the soil moisture content. In the embodiment illustrated in FIG. 2 the processing of the frequency f_{osc} of the sensed signal includes dividing the sensed frequency using the frequency divider 206 to provide a lower frequency signal f_{count} for further processing by the controller 210. In the present case, the further processing entails, counting the number of cycles of the f_{count} that occur in a 20 mS period. This number forms the basis of the ‘soil count’ that is stored for the normalising points (Air and Water) and used on the derivation of the scaled frequency value. The soil count is derived as follows:

Soil Count (F_{S})=20 ms/(1/(f_{osc}/64))

In terms of the other components of the processing module 104, the clock 214 provides a reference signal for establishing processing timing. The gate 208, is controllably switchable by the controller 210 so as to isolate the sensing circuit from the power supply on activation of an ‘idle mode’.

The sensor 112 shown here also includes a temperature sensor 216, which will be described in more detail later.

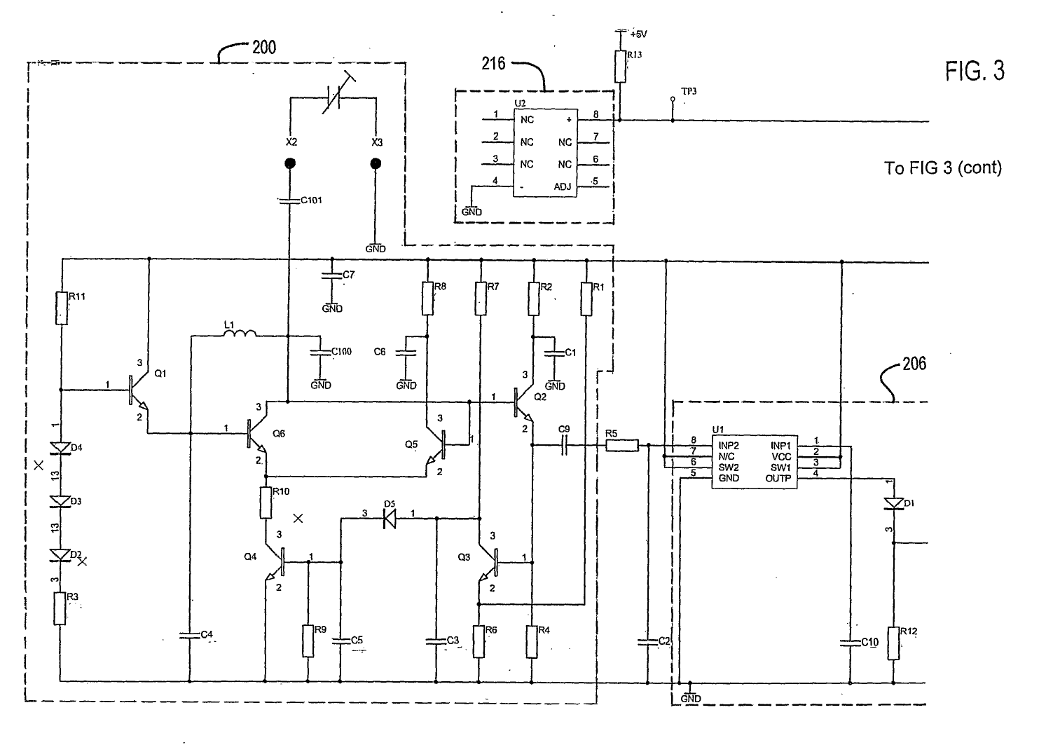

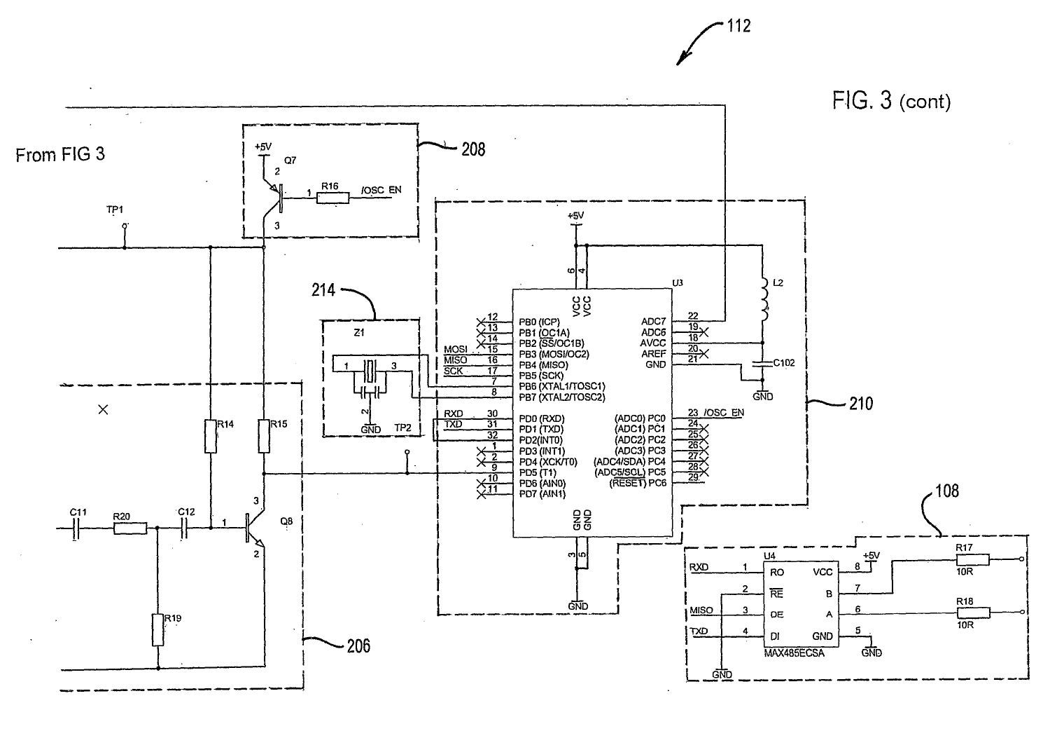

FIG. 3 depicts a circuit diagram for an embodiment of the sensor 112. The illustrated sensor 112 includes a processing module 104 of the type illustrated and described with reference to FIG. 2. For ease of reference, the oscillator 200, the frequency divider 206, the gate 208, the controller 210 (with on-board memory 106/212), the temperature sensor 216, the clock 214 and the bi-directional communications interface 108 are shown in dashed boxes.

The illustrated oscillator 200 includes transistors Q5/Q6 (BFR92A) configured as a Collpitts oscillator with transistor Q2 (BFR92A) as a low impedance emitter follower/buffer. The buffer is coupled through a series capacitor/resistor to provide a low return loss coupling (˜50 ohms) to a frequency prescaler (U1) at 90-170 MHz.

An automatic level control (ALC) circuit, formed by Q3/D5/Q4, is also connected to the emitter of Q2. The ALC circuit varies the bias point of the transistor Q6 to ‘square’ the oscillator's 200 output waveform to provide stable triggering of the frequency prescaler (U1).

In the present case, the sensing elements X2, X3 are planar sensing elements formed as strip lines on a separate printed circuit board (not shown) to enable the sensor 112 to be in close proximity (for example, about 5 mm) to the soil medium, although not in direct contact. In this embodiment, the sensing element printed circuit board (PCB) is directly connected to a main PCB bearing the remainder of the sensor electronics. Thus, in the present case, the sensing element PCB includes both sensing elements X2, X3. More specifically, X2 includes is a 150 mm length of 5 mm wide PCB stripline inductor mounted in ‘free space’, whereas X3 comprises two copper ground planes etched parallel with, and on the same plane as X2, approximately 26 mm apart.

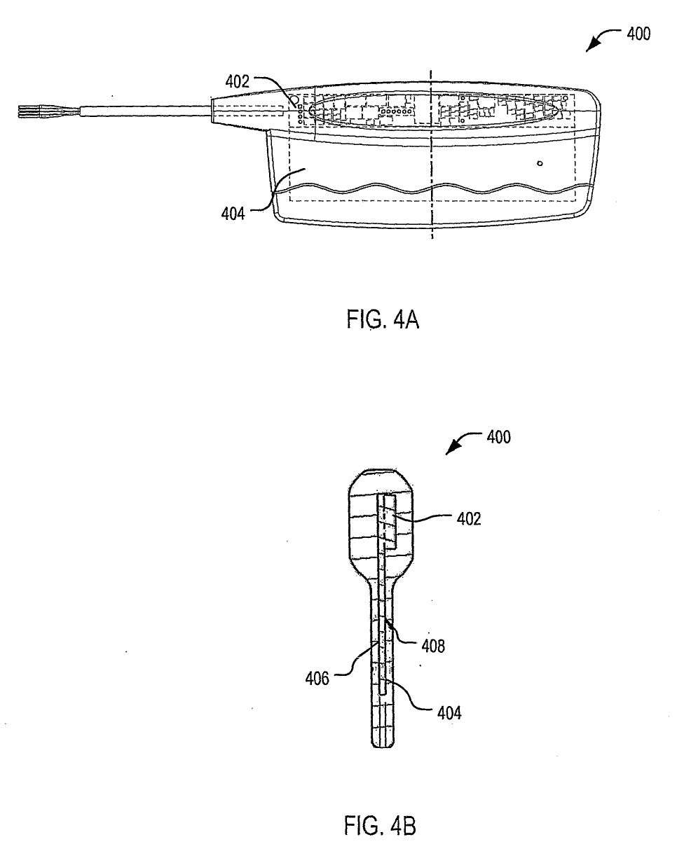

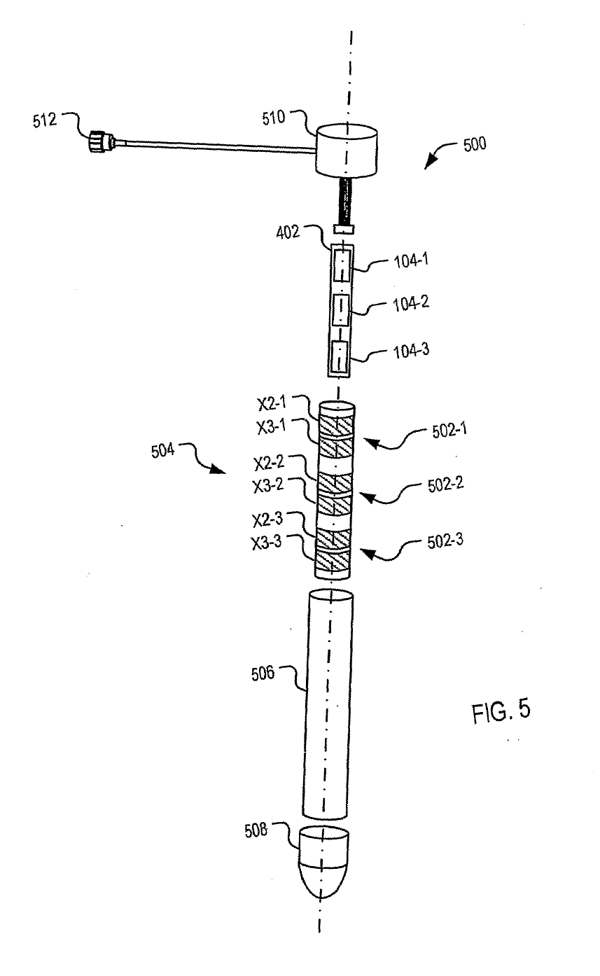

In a sensor that includes planar sensing elements X2, X3, and as is depicted in FIG. 4A and FIG. 4B, the sensor electronics PCB assembly 402 and the sensing elements PCB assembly 404 is mounted in a housing 400, so the flat surfaces 406, 408 (ref. FIG. 4B) of the sensing elements X2, X3 face the soil medium and thus any change in the soil medium changes the dielectric coupling (and thus the capacitance) between the sensor's two sensing elements X2, X3. Thus, in the illustrated embodiment the sensor assembly 400 effectively provides a single level sensor that uses a ‘double sided’ blade configuration that effectively reduces sensor air gaps, and thus enhances accuracy and sensitivity. It is to be appreciated that whilst the above description described a sensor 112 including planar sensing elements X2, X3, it is not intended that the present invention be restricted to such sensors. In this respect, the mechanical configuration of the sensing elements X2, X3 and indeed the number of electrode pairs formed using respective sensing elements X2, X3 may vary. In this respect, FIG. 5 depicts a sensor assembly 500 that includes three pairs 502-1, 502-2, 502-3 of respective cylindrical sensing elements X2-1, X3-1, X2-2, X3-2, X2-3, X3-3 arranged on a sensor body 504 for insertion into a sensor housing 506 with an end cap 508 and a lid 510. Thus, in such an embodiment, the sensor assembly 500 effectively provides three sensors. In addition, in the embodiment illustrated in FIG. 5, the sensor electronics PCB assembly 402 includes a different processing module 104-1, 104-2, 104-3 for each sensor, but may include a single communications interface (not shown) for communicatively coupling to an external communications device via connector 512. In the present case, each of the three sensors has a separate sensor identifier.

Returning now to FIG. 3, in use the resultant capacitance between the sensing elements X2 and X3 varies from 5 pF (in Air) to 32 pF (in Water).

The oscillator 200 is formed by the inductor L1 (100 nH-5% tolerance) and the capacitor C100 (shown here as 22 pF). The series combination capacitance (Cx) of C101 (shown here as 47 pF) and the sensing elements X2 and X3 provides the tuning element of the oscillator 200.

In the present case, the series capacitance C101 is connected to sensing electrode X2 and has been selected so that the sensor's stripline inductor appears capacitive (non-resonant) across the complete operating frequency range of the oscillator irrespective of the environment of the sensor. In other words, irrespective of whether the sensor's PCB assembly is installed in a housing or not, in water or air and the like.

In the illustrated embodiment, the ratio between C100 and the series combination capacitance of C101/Sensor has been selected to resonate the inductor L1 at 163.84 MHz (Cx=26.5 pF) in air and at 93.38 MHz (Cx=4 pF) when the sensor is fully submerged in water. However, the actual frequencies at which the sensor operates (in both air and water) are not particularly critical. Indeed, a normalisation procedure, applied to measure the ‘in air’ and ‘fully submerged in water’ frequencies, can compensate for differences of up to 20% between sensors.

During a normalisation process, each sensor is tested in both air and water. The frequency of oscillation under these test conditions are known as the air and water count, respectively, and are stored in on-board memory (such as an EEPROM) in the processing module as normalisation values. The stored normalisation values are used during the processing of the signal parameter value to compensate for differences between individual sensors by normalising the sensed signal parameter value in the soil medium. The normalisation values typically remain with the sensor throughout its life and, provided that there are no physical or electrical changes to the sensor module, it should not be necessary to re-normalise the sensor module after manufacture.

We have found that manufacturing differences between sensors result in less than 5% differences in the standard operating frequencies (in other words, the ‘in air’ and ‘fully submerged in water’ frequencies). Such a difference is well within the capability of the firmware to compensate. Actual frequencies measured during the normalization procedure are stored in the embedded controllers EEPROM.

Allowable frequencies for normalisation purposes are as follows:
Air: 127.79 to 163.84 MHz
Water: 93.38 to 114.6 MHz

Once normalised, the frequency of oscillation in air and water should not change.

Returning now to FIG. 3, the output of the oscillator 200 is coupled from Q2 to a frequency divider 206 (shown here as a MB506 pre-scaler, designated U1). In the present case, the frequency divider 206 divides the output frequency of the oscillator 200 by a factor of sixty-four to simplify the task of measuring the frequency in the low power embedded microcontroller.

The controller 210 receives the output of the frequency divider 206, and under the control of installed application code, counts the number of cycles of the frequency divider's 206 output signal. The number of counts is then converted to a scaled frequency data value.

In use, the conversion of the number of counts into a scaled frequency data value is performed using normalisation values derived for a sensor during the normalisation process. In this respect, a scaled frequency data value is a dimensionless number in the range 0 to 1 which, in the present case, is defined by the following equation:

$${S}_{F} = \frac{( {F}_{a} - {F}_{s} )}{( {F}_{a} - {F}_{W} )}$$

where:

F_{α} is the frequency of oscillation in air (air count);

F_{S} is the frequency of oscillation in the soil medium (soil count); and

F_{W} is the frequency of oscillation in water.

Software in the external communications device in communications with the sensor 112 can then convert the scaled frequency to volumetric soil moisture content by means of a calibration table or formula.

In terms of the remaining components illustrated in FIG. 3, during non measurement times Q7 acts as a power switch and removes all power from the sensing circuit so as to reduce load current to very low levels. In addition, when the sensor is not active, the output of the pre-scaler (and hence the rest of the sensor electronics) is isolated from the output of the oscillator 200 by the reverse biased diode D1.

In relation to the temperature sensor 216, the integrated circuit U2 in conjunction with the controller 210 (U3) effects a closed loop temperature compensation on the oscillator 200 by applying a variable factor to the measured frequency in accordance to a known calibration curve stored with in the controller's 210 on-board memory (such as in EEPROM memory). The provision of a temperature sensor 216, and the subsequent temperature compensation processing of the sensed signal parameter value based on temperature measurement, may provide a scaled data value that has been compensated for diurnal fluctuations directly in the sensor.

As will be appreciated, and although not illustrated, the sensor 112 also requires a power source. In the present case, the power source is derived from the externally supplied +7.5V to +16V DC. This supply is sub-regulated with a standard LDO (not shown) to provide a constant +5V supply. Peak current requirement (that is, when the sensor is energised) is typically 65 mA. The duration of this ‘active’ current is for only 30 mS (+−5 mS). The idle current is in the order of 1 mA (+−100 uA).

In terms of the communications interface, the illustrated embodiment includes a RS485 compatible communications device (U3) for converting the output of the controller 210 into a RS485 type output signal and for receiving an RS485 type signal from the external device and converting that signal into an input signal compatible with the controller 210. As will be appreciated, and in terms of an output message from the sensor, the communications device (U3) converts a message that has been assembled by the controller 210 using a suitable communications mode.

Thus, the sensor 112 will provide a communications mode for communicating the scaled data value and the sensor identifier to the external communications device. Examples of two suitable communications mode include an ASCII output mode and a binary output mode. Further detail each of these modes is provided below.

### Example 1

### ASCII Output Mode

In this mode the sensor 112 responds to polled commands from the external communications device and respond accordingly with data formatted in simple ASCII text strings. The sensor identifier for this mode is a simple two-digit ASCII number in the range of ‘00’through ‘98’. The address ‘99’ is reserved as a broadcast address that will require all sensors connected to the external communications device to respond. The ASCII output mode has no check summing or error checking and is typically used for short distance communications.

### Example 2

### Binary Output Mode

In this mode the sensor 112 implements a binary ‘IP addressed’ type of protocol that enables data-packets communicated form the sensors 112 to be sent via intermediate telemetry/communication channels and yet still retain the sensor's applicable engineering units and or scaling. It is envisaged that such a protocol will enable the communication of digital data in a format that supports ‘plug n play’ type capabilities.

Additionally, in this mode, the sensor 112 has the ability to make autonomous readings without an external communications device invoking a sensing cycle. A sensor 112 that has the ability to make autonomous readings is expected to enable immediate control of third party equipment in response to changes in moisture levels of the soil medium.

As explained previously, the actual sensor readings may be averaged statistically, for example by a simple IIR filter (moving average), after which the immediate and averaged values are stored. The IIR filter may have a programmable sample count from, for example, one to ten sensing cycles.

The timing interval for the autonomous mode is also programmable, via the bi-directional communications interface 108. For example, the timing interval may be programmed from 0 to 255 Minutes, with 0 being equivalent to an immediate reading.

The binary output mode provides a message including a packet header and data segment which are encapsulated with two separate sixteen bit cyclic redundancy check (CRC) digits.

In addition, the binary output mode also embeds the sensor identifier, in the form of a unique product code (such as a unique serial number), that forms the sensors electronic serial number or ESN. Advantageously, the use of such a serial number permits the sensor to provide a ‘plug and play’ type capability.

### Example 3

### Data Communications Protocol

In the binary mode, a data output format protocol is for communications between a sensor 112, or plural sensors, and one or more external communication devices (herein referred to as a ‘data node’). More specifically, in the binary output mode, the data output format includes a binary data stream of packets, which can be either a request, or a response to a request from a data node.

On receipt of a data communication from a sensor 112, the data node recognises the start of a data packet (herein referred to as a ‘message’) by a synchroniser (in the present case, ‘0×AA’). In this respect, in this example all messages begin with a synchroniser as the first byte of a ‘packet header’. As will be appreciated, a message may contain one data packet, or plural data packets.

In the present example, request packets begin with a synchroniser and have at least eight bytes. On the other hand, response packets begin with a synchroniser and also contain at least the packet header and the responding sensor's unique device identifier (UDI), which together contain twenty bytes.

On receipt of a message from a sensor, and after the data node recognises the synchroniser, the data node then checks whether the message is the start of a packet header (which is this example is eight bytes long). The last two bytes in a packet header contain its CRC checksum. In this respect, as the data node reads the message (in the form of a byte stream) it applies a checksum formula and compares the result with the checksum in the packet. If there is not a match the data is ignored.

Table 1 lists an example of a suitable eight-byte packet-header format.

TABLE 1
Packet Header Format

| Packet | | | |
|---|---|---|---|
| Location | Contains | | |
| (byte) | (Hex) | Description | |
| 1 | AA | Synchroniser | Reserved code that indicates the start of a header |
| 2 | LO | Destination | This is the Session Id for attached slave devices |
| 3 | HI | Address | Data Node Address = 00 00 |
| 4 | 20-3F | Packet Id | Indicates the purpose of the Packet, which affects |
| | | | the data segment format as well as its content |
| 5 | 00-80 | Data Length | The number of bytes of data appended to the header |
| 6 | 00 | | to complete the Packet (Min = 0, to Max = 128) |
| 7 | | CRC | The code that indicates whether the Packet received |
| 8 | | | was complete. |

Some requests use a data packet with only a packet header, whereas other data packets will include a ‘data segment’. Typically, a data segment will follow a packet header and the length of the data segment (in this example, up to a maximum of 128 bytes) is indicated in bytes five and six within the associated packet header.

The data segment is followed by a CRC checksum that validates the data segment.

In the present case, the maximum size of a data packet, including the header packet and CRC, is one-hundred and thirty eight bytes. As depicted in Table 2, the last 2 bytes of a response contains a CRC to confirm the length of its data segment.

TABLE 2
Last 2 bytes of the Data section

| Packet | | |
|---|---|---|
| Location | | |
| (byte) | Description | |
| n − 1 | Data CRC | The data CRC is used to confirm the length of |
| N | | the data segment of the Packet. The length of |
| | | the Packet is given in the Packet Header. |

Packets from the data node to other sensors are request packets and have even numbered packet identifiers. Sensors reply to a request packet with one or more response packets, which have a packet identifier one greater than the corresponding request packet.

All response packets begin with the packet header and unique device identifier for the sensor that collected the requested data. Sensor location information is provided within a unique device identifier block, which also includes product code and firmware version information, as is depicted in Table 3.

TABLE 3
Unique Device Identifier Block

| | |
|---|---|
| Location | |
| (byte) | Description |

| | | |
|---|---|---|
| 1 | Device Serial | Unique Device Identifier |
| 2 | Number | |
| 3 | (DSN) 4 byte | |
| 4 | unsigned integer | |
| 5 | Product code | |
| 6 | 5 byte character | |
| 7 | field | |
| 8 | | |
| 9 | | |
| 10 | Hardware revision | |

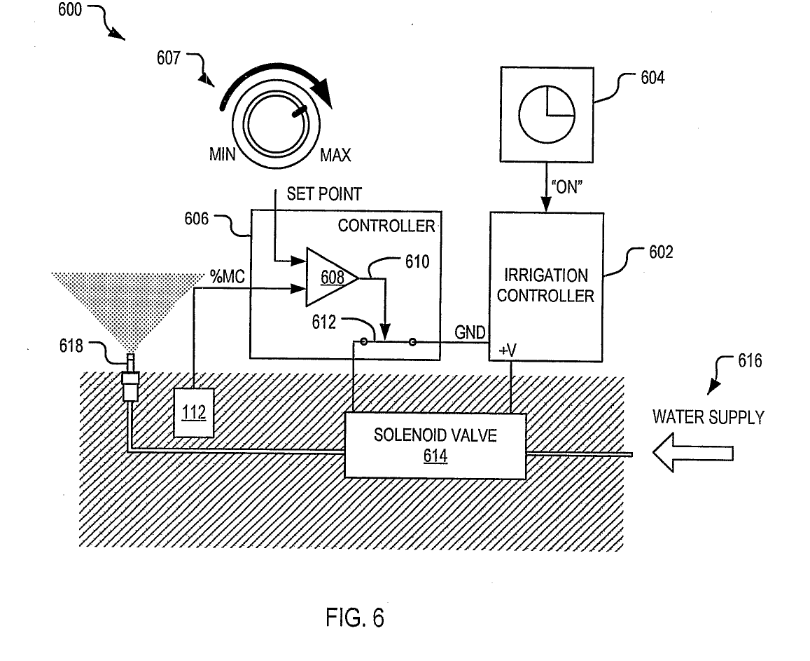

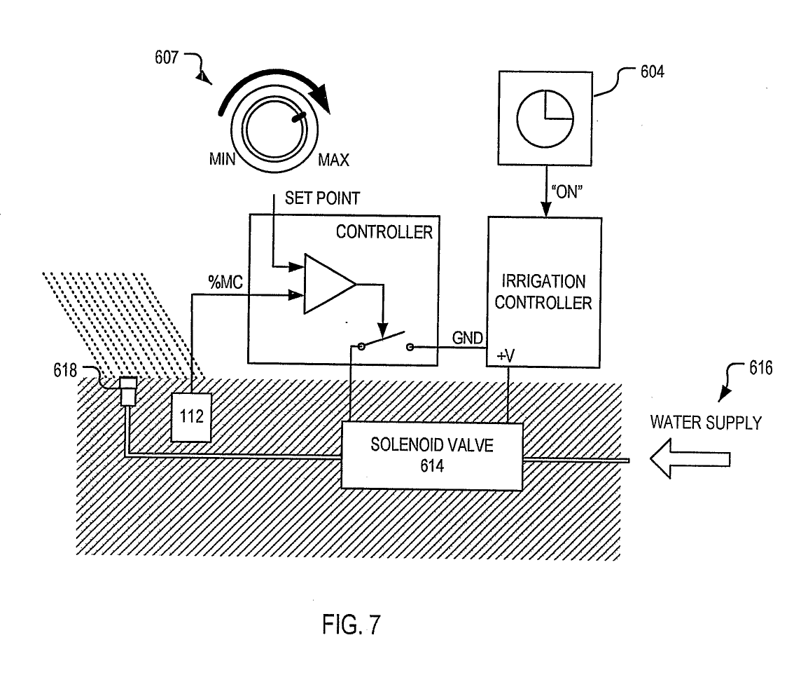

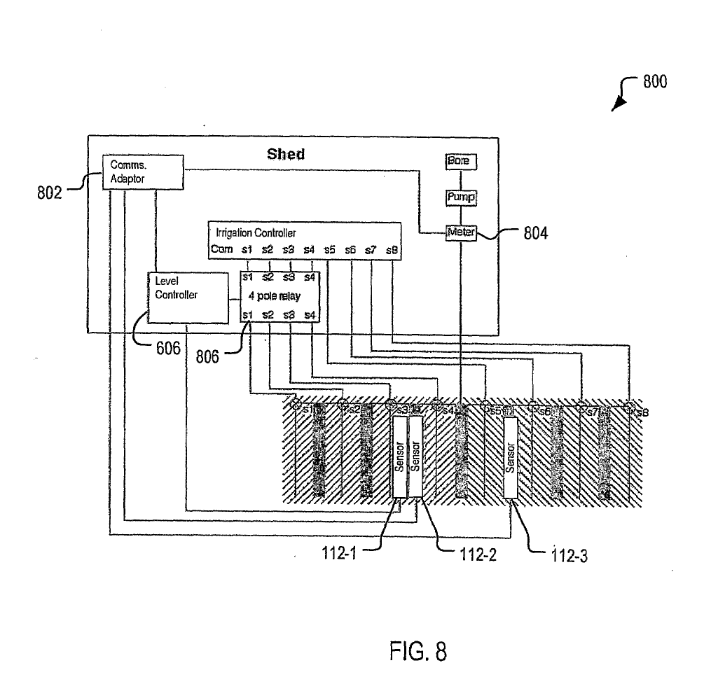

FIG. 6, FIG. 7 and FIG. 8 depict example applications of a sensor 112 in accordance with an embodiment of the present invention. It is to be appreciated that although the depicted examples will make reference to the sensor 112, a sensor 100 may also be used. The actual sensor used will depend upon the communication requirements.

The example application depicted in FIG. 6 and FIG. 7 depicts an irrigation control system 600 for controllably interrupting a programmed irrigation cycle operating on a programmable irrigation controller 602 under the control of a timer 604. In illustrated embodiment, the combination of the sensor 112 and the external communications device 606 acts in a manner that is a moisture content equivalent to a temperature thermostat. As a result, the application of the system depicted in FIG. 6 and FIG. 7 may also extend to include water level detection in water storage devices, such as rain-water tanks and the like.

However, as shown, the irrigation control system 600 includes a sensor 112, and an external communications device 606 including a user-settable input 607 for entering a high-set point level value. In this way, the soil moisture level of the soil medium can be effectively controlled via the user-settable input 607 so that irrigation is interrupted if the soil is already too wet, or if the soil gets too wet while watering.

In the present case, the external communications device 606 also includes a comparator 608 for comparing the scaled data value communicated by the sensor 112 with the high-set point value to provide a control signal 610 responsive to the comparison.

The external communications device 606 also includes a switch 612 (shown here as a normally-closed switch) responsive to the control signal 610 so that whenever the scaled data vale (shown here as % MC) from the sensor 112 exceeds the high-set point, the switch 612 actuates to an open position. As will be appreciated, when the switch 612 is in the closed position a current path is provided between +V and GND which in turn provides electrical power to the solenoid valve 614 to permits flow of water from the water supply 616 to the sprinkler head. On the other hand, and as is depicted in FIG. 7, when the switch 612 is in the open position, such as will be the case when the soil moisture content exceeds the high-set point value, the current path becomes an open circuit and electrical power is isolated from the solenoid valve 614, in which case the valve 614 shuts and the water supply 616 is isolated from the sprinkler head 618. Of course, it will be appreciated that in other embodiments the configuration of the switch, in terms of the normally-open or normally closed configuration will depend upon the type of the solenoid valve, and in particular the type of activation required.

FIG. 8 depicts an irrigation system including multiple sensors 112, each of which is communicatively coupled to an external communications device 802, 606. The system 800 depicted in FIG. 8 is an example of a multi-zone type installations with multiple watering systems. Such an installation provides correct watering where, for example, different plants have different watering requirements.

In this case, external communications device is a protocol converter for converting the output of the sensors connected thereto into a format compatible with the meter. On the other hand, external communications device 606 is of the same type described with reference to FIG. 6 and FIG. 7. However, in this case, rather than actuating a single switch, the external communications device illustrated in FIG. 8 actuates a relay 804 providing plural switches so as to actuate the solenoid valves connected thereto. In other words, the system 800 provides the capability to provide a high-set point type control of multiple sprinklers.

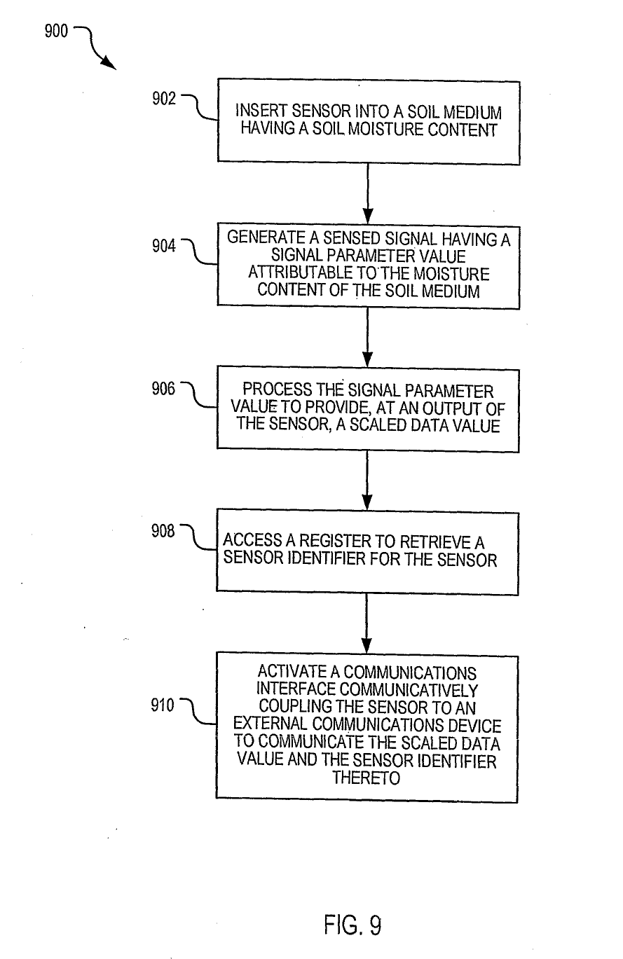

FIG. 9 depicts a flow diagram 900 for a method of obtaining a measurement value from a sensor of either type 100, 112 described earlier with reference to FIG. 1 and FIG. 2 respectively. As show, and as explained in more detail earlier, the method includes inserting 900 the sensor into a soil medium having a soil moisture content. The sensor 100, 112 (ref. FIG. 1/FIG. 2), when activated, then generates 904 a sensed signal having a signal parameter value attributable to the moisture content of the soil medium. The processing module 104 (ref. FIG. 1/FIG. 2) on board the sensor 100, 112 is then controlled, usually by a suitable computer software program, to:
1. process 906 the signal parameter value to provide, at an output of the sensor 100, 112, a scaled data value;
2. access 908 a register to retrieve a sensor identifier for the sensor; and
3. activate 910 a communications interface communicatively coupling the sensor 100, 112 to an external communications device to communicate the scaled data value and the sensor identifier thereto.

In conclusion, it must be appreciated that there may be other various and modifications to the configurations described herein which are also within the scope of the present invention.

1. A sensor for sensing moisture content of a medium such as soil, the sensor including:
a sensing circuit for generating a sensed signal having a signal parameter value attributable to the moisture content of the medium;
a processing module for processing the signal parameter value to provide, at an output, a scaled data value;
a register for storing a sensor identifier for the sensor; and
a communications interface for communicatively coupling the sensor to an external communications device to communicate the scaled data value and the sensor identifier thereto.

2. A sensor according to claim 1 wherein the communications interface includes a bi-directional communications interface and wherein the processing of the signal parameter value is configurable via the bi-directional communications port.

3. A sensor according to claim 2 wherein the sensing circuit includes an oscillator, the oscillator including a paired electrode arrangement forming a capacitive element having a value of capacitive reactance attributable to a dielectric constant of the medium, and wherein the signal parameter value of the sensed signal is a resonant frequency of the oscillator.

4. A sensor according to claim 3 wherein the sensor further includes an integral temperature sensor for sensing the temperature within a sensed zone of the medium and wherein the processing applies a temperature compensation factor according to the sensed temperature so that the scaled data value is temperature compensated.

5. A sensor according to claim 2 wherein the bi-directional communications interface is configured to communicate packet based data.

6. A sensor according to claim 1 wherein the sensing circuit includes an oscillator configured such that when the sensor is inserted into a soil medium the oscillator generates a sensed signal having a frequency signal parameter value (f_{osc}) that varies according to the dielectric constant of the medium.

7. A sensor according to claim 6 wherein the oscillator includes a pair of sensing elements coupled in parallel with a series LC arrangement represented as a bulk capacitance and a bulk inductance, and wherein the bulk capacitance and the bulk inductance form a resonant circuit having a resonant frequency f_{osc}.

8. A sensor according to claim 7 wherein the pair of sensing elements includes either a pair of co-planar planar conductive electrodes or a pair of co-axially arranged cylindrical conductive electrodes.

9. A sensor according to claim 8 wherein the pair of co-planar planar conductive electrodes comprise a pair of strip lines and wherein a series capacitance is connected to one of the electrodes so that sensor's strip line inductor appears capacitive (non-resonant) across the range operating frequency range of the oscillator.

10. A sensor according to claim 9 wherein the ratio between the series capacitance and a series combination of the capacitance of the series capacitance and conductive electrode is selected to resonate the bulk inductance at a frequency in the range of substantially 127.79 MHz to 163.84 MHz (F_{α}) in air, and at a frequency in the range of substantially 93.38 MHz to 114.6 MHz (F_{W}) when the sensor is fully submerged in water.

11. A sensor according to claim 10 wherein the scaled data value S_{F} is a dimensionless number in the range 0 to 1 which is given by
$${S}_{F} = \frac{( {F}_{a} - {F}_{s} )}{( {F}_{a} - {F}_{W} )}$$
where:
F_{S} is the frequency of oscillation in the medium (soil count).

12. A sensor according to claim 1 wherein the sensing circuit includes an oscillator configured such that when the sensor is inserted into a soil medium the oscillator generates the sensed signal, the sensed signal having a frequency signal parameter value (f_{osc}) that varies according to a dielectric constant of the soil medium, and wherein the processing module processes, over a predetermined gate time, the sensed signal to derive a count value (F_{S}) indicative of the number of counts of the sensed signal detected during the gate time, and wherein providing the scaled data value includes processing the count value (F_{S}), and frequency values indicative of in air (F_{α}) and in water (F_{W}) frequencies respectively.

13. A sensor according to claim 12 wherein the scaled data value S_{F} is a dimensionless number in the range 0 to 1 which is given by
$${S}_{F} = \frac{( {F}_{a} - {F}_{s} )}{( {F}_{a} - {F}_{W} )}$$
where:
F_{S} is the frequency of oscillation in the soil medium (soil count).

14. A sensor for sensing moisture content of a medium such as soil, the sensor including:
a sensing circuit for generating a sensed signal having a signal parameter value attributable to the moisture content of the medium, the sensing circuit including an oscillator configured such that when the sensor is inserted into the medium the oscillator generates the sensed signal, the sensed signal having a frequency signal parameter value (f_{osc}) that varies according to a dielectric constant of the medium;
a processing module for processing the signal parameter value to provide, at an output, a scaled data value (S_{F}), the processing including deriving a count value (F_{S}) of the sensed signal (f_{osc}) detected during a gate time, and processing the count value (F_{S}), and frequency values indicative of in air (F_{α}) and in water (F_{W}) frequency values respectively to calculate the scaled data value S_{F} wherein:
$${S}_{F} = \frac{( {F}_{a} - {F}_{s} )}{( {F}_{a} - {F}_{W} )} ;$$
a register for storing a sensor identifier for the sensor; and
a communications interface for communicatively coupling the sensor to an external communications device to communicate the scaled data value and the sensor identifier thereto.

15. A sensor according to claim 14 wherein the frequency values (F_{α}) and (F_{W}) are stored in memory on board the sensor.

16. A computer readable medium containing a computer software program for programming a sensor for sensing moisture content of a soil medium, the software program being executable by a processor module to cause the sensor to:
generate a sensed signal having a signal parameter value attributable to the moisture content of the medium;
process the signal parameter value to provide, at an output, a scaled data value;
access a register to retrieve a sensor identifier for the sensor; and
activate a communications interface communicatively coupling the sensor to an external communications device to communicate the scaled data value and the sensor identifier thereto.

17. A computer readable medium according to claim 16 wherein the step to process the signal parameter value includes deriving a count value (F_{S}) of the sensed signal (f_{osc}) detected during a gate time, and processing the count value (F_{S}), and frequency values indicative of in air (F_{α}) and in water (F_{W}) frequency values respectively to calculate the scaled data value S_{F} wherein:
$${S}_{F} = \frac{( {F}_{a} - {F}_{s} )}{( {F}_{a} - {F}_{W} )} .$$

18. A computer readable medium according to claim 17 wherein the step to process the signal parameter value further includes applying a temperature compensation factor according to a sensed temperature value obtained from a temperature sensor for sensing temperature within a sensed zone of the soil medium.

19. A method of obtaining a measurement value from a sensor for sensing moisture content of a medium such as soil, the method including:
inserting the sensor into the medium having a moisture content;
the sensor generating a sensed signal having a signal parameter value attributable to the moisture content of the medium;
controlling a processing module associated with the sensor to:
process the signal parameter value to provide, at an output of the sensor, a scaled data value;
access a register to retrieve a sensor identifier for the sensor; and
activate a communications interface communicatively coupling the sensor to an external communications device to communicate the scaled data value and the sensor identifier thereto.

20. A method according to claim 19 wherein the step to process the signal parameter value includes deriving a count value (F_{S}) of the sensed signal (f_{osc}) detected during a gate time, and processing the count value (F_{S}), and frequency values indicative of in air (F_{α}) and in water (F_{W}) frequency values respectively to calculate the scaled data value S_{F} wherein:
$${S}_{F} = \frac{( {F}_{a} - {F}_{s} )}{( {F}_{a} - {F}_{W} )} .$$

21. A method according to claim 20 wherein processing the signal parameter value further includes applying a temperature compensation factor according to a sensed temperature value obtained from a temperature sensor for sensing temperature within a sensed zone of the medium.

22. An irrigation control system for controllably interrupting a programmed irrigation cycle, the irrigation control system including:
a sensor including:
a sensing circuit for generating a sensed signal having a signal parameter value attributable to moisture content of a medium such as soil;
a processing module for processing the signal parameter value to provide, at an output, a scaled data value;
a register for storing a sensor identifier for the sensor; and
a communications interface for communicatively coupling the sensor to an external communications device to communicate the scaled data value and the sensor identifier thereto; and
an external communications device including:
a user-settable input for entering a high-set point level value; and
a comparator for comparing the scaled data value with the high-set point value to provide, responsive to the comparison, a control signal for actuating a switching means to interrupt the programmed irrigation cycle.

23. (canceled)

24. (canceled)
